(19) United States
(12) Patent Application Publication
(10) Pub. No.: US 2014/0036188 A1
(43) Pub. Date: Feb. 6, 2014

(54) Liquid Crystal Display Device, Array Substrate and Manufacturing Method Thereof

(71) Applicant: Cheng-hung Chen, Shenzhen (CN)

(72) Inventor: Cheng-hung Chen, Shenzhen (CN)

(21) Appl. No.: 13/641,112

(22) PCT Filed: Aug. 10, 2012
(86) PCT No.: PCT/CN12/79928

§ 371 Date: Oct. 13, 2012

(30) Foreign Application Priority Data
Aug. 1, 2012 (CN) 201210271440.1

(51) Int. Cl. G02F 1/136; H01L 33/08

(52) U.S. Cl. 349/43; 257/59; 257/72; 438/34; 257/E33.053

(57) ABSTRACT

The present invention provides a liquid crystal display device, array substrate and manufacturing method thereof. The array substrate includes a substrate, first metal layer, first isolator layer, transparent conductive layer, second isolator layer and second metal layer, wherein the first metal layer forms scan line, gate of TFT and common electrode; first isolator layer is on top of first metal layer; transparent conductive layer forms source and drain of TFT, and pixel electrode; second isolator layer is on top of transparent conductive layer; second metal layer forms data line; in addition, array substrate further includes auxiliary electrode, and the auxiliary electrode is formed by at least one of first metal layer and second metal layer. As such, scan line and/or data line can co-transmit signal with auxiliary electrode to reduce impedance so as to improve display quality of liquid crystal display.

### BACKGROUND OF THE INVENTION

1. Field of the Invention

The present invention relates to the field of liquid crystal displaying techniques, and in particular to a liquid crystal display device, array substrate and manufacturing method thereof.

2. The Related Arts

The manufacturing process for liquid crystal display panel usually includes an array process, a cell process and a module process. The array process is to manufacture the thin film transistor (TFT) glass substrate (also called array substrate). As the first process of the manufacturing process for liquid crystal display panel, the quality of the manufactured TFT glass substrate has great impact on the subsequent processes, or even determines the quality of the liquid crystal display panel.

The array process includes five-mask process (5PEP process). Referring to FIG. 1 and FIG. 2, FIG. 1 is a schematic view showing the structure of pixel layout of a known array substrate, and FIG. 2 is a cross-sectional view of the array substrate of FIG. 1 along the A-B direction. In the known 5PEP process, the first step is to form gate 110 of TFT 140, gate line or scan line 111 and common electrode 120 on first metal (M1) 11. Then, first isolator layer 12 is formed on top of first metal layer 11, and a semiconductor layer 13 is formed on top of first isolator layer 12 corresponding to first metal layer 11 forming gate 110 of TFT 140. Then, second metal layer 14 is formed on top of first isolator layer 12 and semiconductor layer 13, for forming data line 141, source 142 and drain 143 of TFT 140. Then, second isolator layer 15 is formed on top of second metal layer 14 and first isolator layer 12. Finally, transparent conductive layer 16 is formed on top of second isolator layer 15, for forming pixel electrode (PE) 161.

At present, as the demands on display quality of liquid crystal display device with high frame rate or high resolution increase, it is necessary to reduce the impedance of scan line 111 and data line 141.

Referring to FIG. 3, FIG. 3 is a schematic view showing the structure of the pixel layout of array substrate reducing impedance of scan line and data line in a known technique, wherein FIG. 3 is an improvement over the array substrate shown in FIG. 1 and FIG. 2 to achieve reducing impedance of scan line 110 and data line 141. As shown in FIG. 3, FIG. 3 is to form second metal layer 14 at partial area of first metal layer 11 forming scan line 110 in FIG. 1 so as to accelerate the scan signal propagation capability of scan line 110, and to switch scan signal between first metal layer 11and second metal layer 14 through pixel electrode 161 formed by via hole (VIA) 17 and transparent conductive layer 16. Similarly, FIG. 3 forms first metal layer 11 at partial area of second metal layer 14 forming data line 141 in FIG. 1 so as to accelerate the data signal propagation capability of data line 141, and to switch data signal between first metal layer 11 and second metal layer 14 through pixel electrode 161 formed by via hole 17 and transparent conductive layer 16.

The pixel layout of FIG. 3 can reduce the impedance of scan line and data line without increasing cost. However, via hole 17 and transparent conductive layer 16 are required to switch scan signal or data signal between corresponding first metal layer and second metal layer. Also, transparent conductive layer 16 has higher impedance and the interface impedance between transparent conductive layer 16 and first metal layer 11 or second metal layer 14 is also higher.

Therefore, the effect of using the structure in FIG. 3 to reduce impedance of scan line and data line is not good. Furthermore, increasing a large number of via holes on pixel electrode will reduce the opening ratio and luminance of pixel electrode, resulting in poor display quality of liquid crystal display device.

### SUMMARY OF THE INVENTION

The technical issue to be addressed by the present invention is to provide a liquid crystal display device, array substrate, and manufacturing method thereof able to reduce impedance of scan line and data line so as to improve display quality of liquid crystal display device.

The present invention provides an array substrate, the array substrate comprises: a substrate; a first metal layer, disposed on top of the substrate for forming scan line, gate of TFT and common electrode; a first isolator layer, disposed on top of the first metal layer; a transparent conductive layer, disposed on top of first isolator layer for forming source and drain of TFT and pixel electrode, pixel electrode being connected to drain of TFT; a second isolator layer, disposed on top of transparent conductive layer, the second isolator layer being disposed with first via hole at area corresponding to source of TFT; a second metal layer, disposed on top of second isolator layer for forming data line, data line being connected to source of TFT through first via hole; wherein the array substrate further comprising auxiliary electrode, the auxiliary electrode being formed by at least one of first metal layer and second metal layer, the auxiliary electrode being formed by first metal layer, the auxiliary electrode being connected to data line through second via hole of first isolator layer and second isolator layer for reducing impedance of data line, the auxiliary electrode being disposed correspondingly under the data line, and the auxiliary electrode being disposed along the extension direction of data line between the scan line and common electrode; the auxiliary electrode being formed by second metal layer, the auxiliary electrode being connected to scan line through third via hole of first isolator layer and second isolator layer for reducing impedance of scan line, the auxiliary electrode being disposed correspondingly above the scan line, and the auxiliary electrode being disposed along the extension direction of scan line between two adjacent data lines.

According to a preferred embodiment of the present invention, the auxiliary electrode comprises first auxiliary electrode and second auxiliary electrode, the first auxiliary electrode is formed by first metal layer, and the second auxiliary electrode is formed by second metal layer, wherein:

The first auxiliary electrode is connected to data line through second via hole of first isolator layer and second isolator layer for reducing impedance of data line, the first auxiliary electrode is disposed correspondingly under the data line and the first auxiliary electrode is disposed along the extension direction of data line between the scan line and common electrode.

The second auxiliary electrode is connected to scan line through third via hole of first isolator layer and second isolator layer for reducing impedance of scan line, the second auxiliary electrode is disposed correspondingly above the scan line and the second auxiliary electrode is disposed along the extension direction of scan line between two adjacent data lines.

The present invention provides a liquid crystal display device, which comprises: an array substrate, the array substrate comprising: a substrate; a first metal layer, disposed on top of the substrate for forming scan line, gate of TFT and common electrode; a first isolator layer, disposed on top of the first metal layer; a transparent conductive layer, disposed on top of first isolator layer for forming source and drain of TFT and pixel electrode, pixel electrode being connected to drain of TFT; a second isolator layer, disposed on top of transparent conductive layer, the second isolator layer being disposed with first via hole at area corresponding to source of TFT; a second metal layer, disposed on top of second isolator layer for forming data line, data line being connected to source of TFT through first via hole; wherein the array substrate further comprising auxiliary electrode, the auxiliary electrode being formed by at least one of first metal layer and second metal layer, for reducing impedance of scan line and/or data line.

According to a preferred embodiment of the present invention, the auxiliary electrode is formed by first metal layer, the auxiliary electrode is connected to data line through second via hole of first isolator layer and second isolator layer for reducing impedance of data line, the auxiliary electrode is disposed correspondingly under the data line, and the auxiliary electrode is disposed along the extension direction of data line between the scan line and common electrode.

According to a preferred embodiment of the present invention, the auxiliary electrode is formed by second metal layer, the auxiliary electrode is connected to scan line through third via hole of first isolator layer and second isolator layer for reducing impedance of scan line, the auxiliary electrode is disposed correspondingly above the scan line, and the auxiliary electrode is disposed along the extension direction of scan line between two adjacent data lines.

According to a preferred embodiment of the present invention, the auxiliary electrode comprises first auxiliary electrode and second auxiliary electrode, the first auxiliary electrode is formed by first metal layer, and the second auxiliary electrode is formed by second metal layer, wherein:

The first auxiliary electrode is connected to data line through second via hole of first isolator layer and second isolator layer for reducing impedance of data line, the first auxiliary electrode is disposed correspondingly under the data line and the first auxiliary electrode is disposed along the extension direction of data line between the scan line and common electrode.

The second auxiliary electrode is connected to scan line through third via hole of first isolator layer and second isolator layer for reducing impedance of scan line, the second auxiliary electrode is disposed correspondingly above the scan line and the second auxiliary electrode is disposed along the extension direction of scan line between two adjacent data lines.

The present invention provides a manufacturing method of array substrate, which comprises: providing a substrate; disposing a first metal layer on top of the substrate for forming scan line, gate of TFT and common electrode; disposing a first isolator layer on top of the first metal layer; disposing a transparent conductive layer on top of first isolator layer for forming source and drain of TFT and pixel electrode, pixel electrode being connected to drain of TFT; disposing a second isolator layer on top of transparent conductive layer, the second isolator layer being disposed with first via hole at area corresponding to source of TFT; disposing a second metal layer on top of second isolator layer for forming data line, data line being connected to source of TFT through first via hole; wherein further disposing auxiliary electrode, the auxiliary electrode being formed by at least one of first metal layer and second metal layer, for reducing impedance of scan line and/or data line.

According to a preferred embodiment of the present invention, the step of disposing first isolator layer on top of first metal layer further comprises: forming a semiconductor layer on the first isolator layer corresponding to gate of TFT, wherein source and drain of TFT are connected to semiconductor layer respectively.

According to a preferred embodiment of the present invention, the auxiliary electrode is formed by first metal layer, the auxiliary electrode is disposed correspondingly under the data line, and the auxiliary electrode is disposed along the extension direction of data line between the scan line and common electrode; the auxiliary electrode is connected to data line through second via hole of first isolator layer and second isolator layer.

According to a preferred embodiment of the present invention, the auxiliary electrode is formed by second metal layer, the auxiliary electrode is disposed correspondingly above the scan line, and the auxiliary electrode is disposed along the extension direction of scan line between two adjacent data lines; the auxiliary electrode is connected to scan line through third via hole of first isolator layer and second isolator layer.

According to a preferred embodiment of the present invention, the auxiliary electrode comprises first auxiliary electrode and second auxiliary electrode, the first auxiliary electrode is formed by first metal layer, and the second auxiliary electrode is formed by second metal layer, wherein:

The first auxiliary electrode is disposed under the data line and the first auxiliary electrode is disposed along the extension direction of data line between the scan line and common electrode; the first auxiliary electrode is connected to data line through second via hole of first isolator layer and second isolator layer.

The second auxiliary electrode is disposed correspondingly above the scan line and the second auxiliary electrode is disposed along the extension direction of scan line between two adjacent data lines; the second auxiliary electrode is connected to scan line through third via hole of first isolator layer and second isolator layer.

The efficacy of the present invention is that to be distinguished from the state of the art. Through disposing auxiliary electrode formed by at least one of first metal layer and second metal layer for forming scan line and data line, the present invention makes scan signal or data signal to be co-transmitted by auxiliary electrode and scan line or auxiliary electrode and data line during transmitting scan signal or data signal. As such, the signal transmission path is broadened to reduce the impedance of data line or scan line so as to improve the display quality of liquid crystal display device.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the pixel layout structure of a known array substrate;

FIG. 2 is a cross-sectional view of the array substrate of FIG. 1 along the A-B direction;

FIG. 3 is a schematic view showing pixel layout structure of array substrate in known technique to reduce impedance of scan line and data line;

FIG. 4 is a schematic view showing the pixel layout structure of an array substrate according to the present invention;

FIG. 5 is a cross-sectional view showing the array substrate of FIG. 4 along the E-F dash line;

FIG. 6 is a cross-sectional view showing the array substrate of FIG. 4 along the A-B dash line;

FIG. 7 is a cross-sectional view showing the array substrate of FIG. 4 along the C-D dash line;

FIG. 8 is a flowchart of the manufacturing method of array substrate according to the present invention; and

FIG. 9 is a schematic view showing the 5PEP process of the array substrate in FIG. 8.

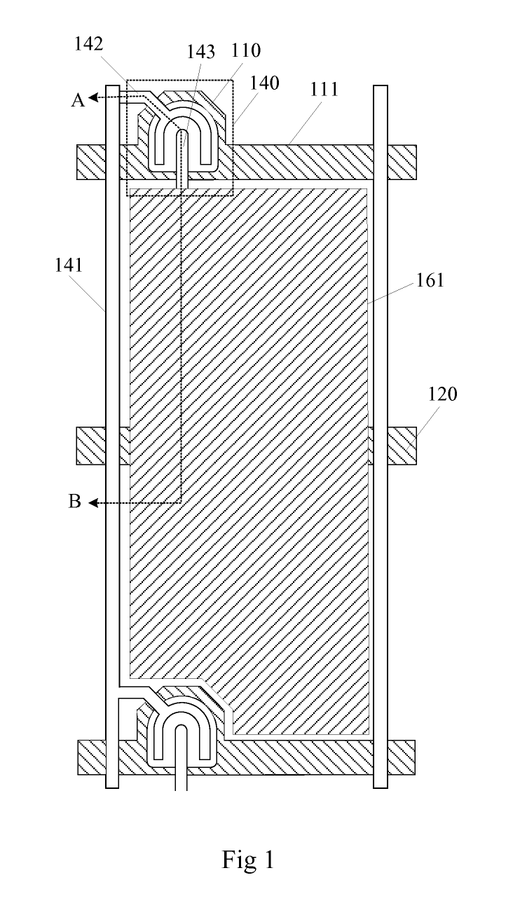

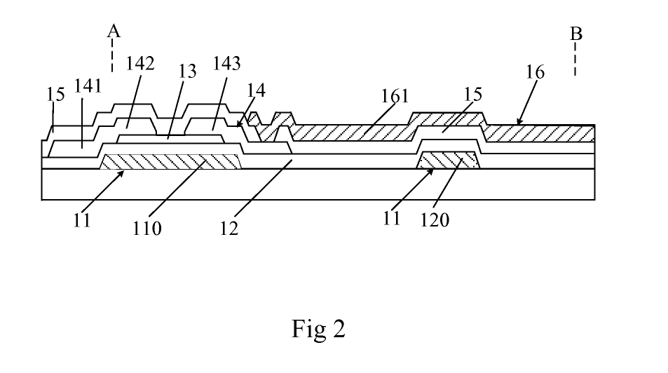

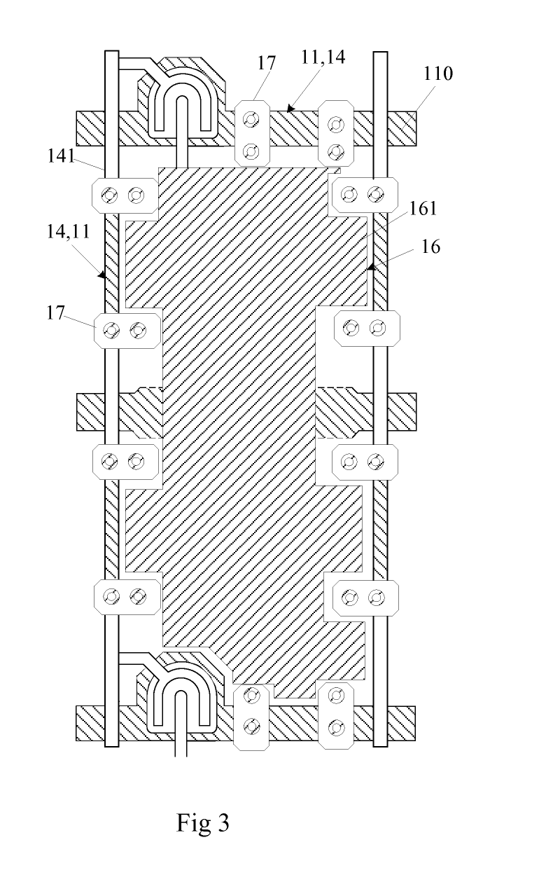

### DETAILED DESCRIPTION OF THE PREFERRED EMBODIMENTS

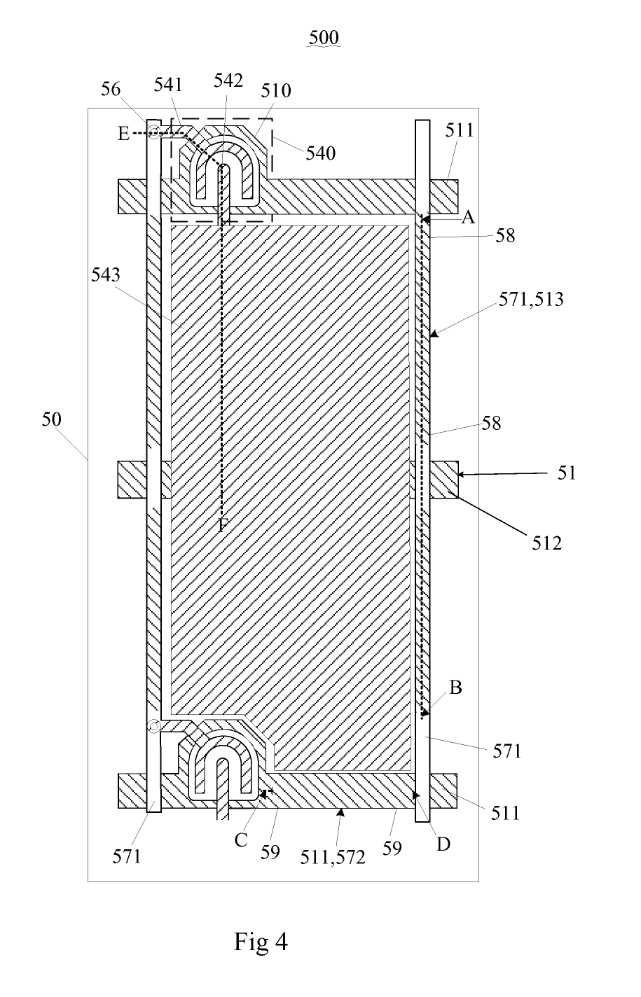

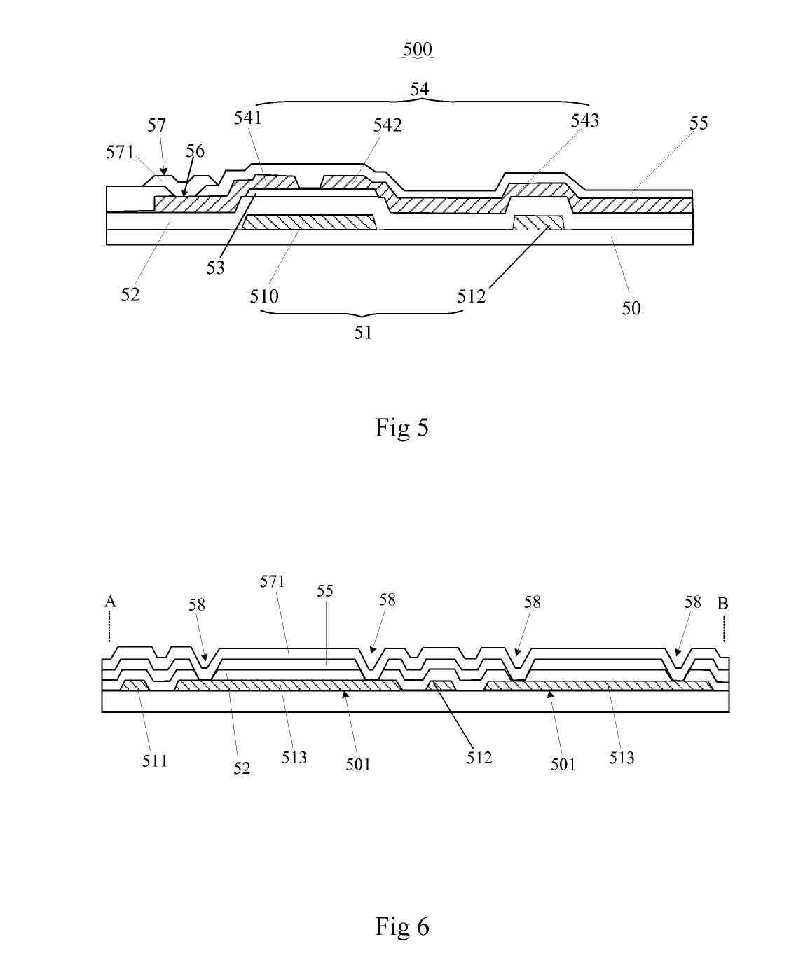

Referring to FIG. 4 and FIG. 5, FIG. 4 is a schematic view showing the pixel layout structure of an array substrate according to the present invention; and FIG. 5 is a cross-sectional view showing the array substrate of FIG. 4 along the E-F dash line. Refer to FIG. 4 first. FIG. 4 only shows a pixel layout structure of substrate 50 of array substrate 50. As shown in FIG. 4, the pixel layout structure comprises two scan line 511 disposed in parallel, two data line 571 disposed in parallel, TFT 540, common electrode 512 and pixel electrode 543.

In the instant embodiment, two scan line 511 are perpendicular to two data line 571 respectively to form a rectangular area. Pixel electrode 543 is disposed within the rectangular area, wherein scan line 511 is connected to gate 510 of TFT 540, data line 571 is connected to source 541 of TFT 540, and drain 542 of TFT 540 is connected to pixel electrode 543. In the instant embodiment, common electrode 512 is disposed between two scan line 511 and below pixel electrode 543. Common electrode 512 and pixel electrode 543 form a capacitor. The specific locations of each element in array substrate 500 are shown in FIG. 5.

As shown in FIG. 5, array substrate 500 comprises substrate 50, first metal layer 51, first isolator layer 52, transparent conductive layer 54, second isolator layer 55 and second metal layer 57. In the instant embodiment, first metal layer 51 is disposed on top of substrate 50 for forming gate 510 of TFT 540, scan line 511 (as shown in FIG. 4) and common electrode 512. First isolator layer 52 is disposed on first metal layer 51. Transparent conductive layer 54 is disposed on top of first isolator layer, wherein transparent conductive layer 54 is for forming source 541 and drain 542 of TFT 540 and pixel electrode 543, and pixel electrode 543 is connected to drain 542 of TFT 540. Second isolator layer 55 is disposed on top of transparent conductive layer 54, and first via hole 56 is disposed at location on second isolator layer 55 corresponding to source 541 of TFT 540. Second metal layer 57 is disposed on top of second isolator layer 55 at location corresponding to source 541 of TFT 540, and second metal layer 57 is for forming data line 571, wherein data line 571 is connected to source 541 of TFT 540 through first via hole 56.

In the instant embodiment, semiconductor layer 53 is further disposed on top of first isolator layer 52 corresponding to gate 510 of TFT 540, and semiconductor layer 53 is connected to source 541 and drain 542, wherein semiconductor layer 53 acts a switch to TFT 540. Specifically:

Gate 510 of TFT 540 acts as control terminal. When scan line 511 supplies scan signal to gate 510 of TFT 540, semiconductor layer 53 is conductive so that TFT 540 is in a conductive state. Source 541 acting as input terminal of TFT 540 is electrically connected to drain 542 acting as the output terminal through semiconductor layer 53. When no scan signal is inputted to gate 510 of TFT 540, semiconductor layer 53 is non-conductive so that TFT 540 is in a closed state, and source 541 and drain 542 are electrically isolated.

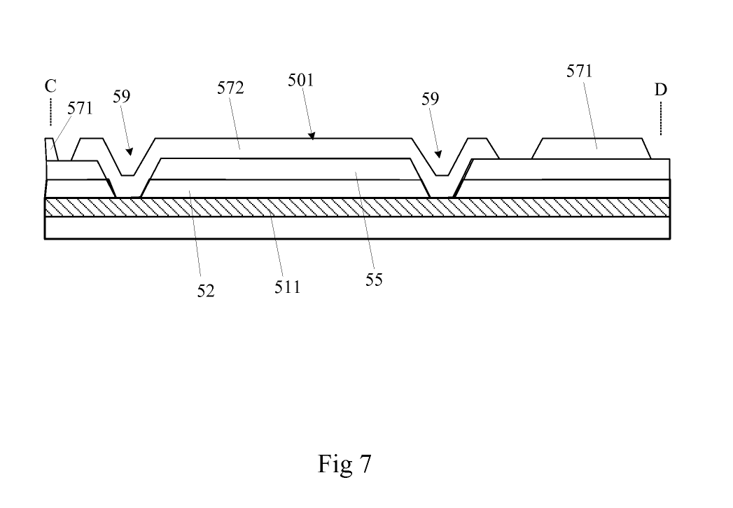

Furthermore, to improve display quality of liquid crystal display device, impedance of scan line 511 and/or data line 571 must be reduced. Refer to FIG. 4, FIG. 6 and FIG. 7, in the present embodiment, array substrate 50 further comprises auxiliary electrode 501, and auxiliary electrode 501 is formed by at least one of first metal layer and second metal layer.

FIG. 6 is a cross-sectional view showing the array substrate of FIG. 4 along the A-B dash line; and FIG. 7 is a cross-sectional view showing the array substrate of FIG. 4 along the C-D dash line.

Refer to FIG. 4 first, auxiliary electrode 501(shown in FIG. 6) comprises first auxiliary electrode 513, and first auxiliary electrode 513is disposed between scan line 511and common electrode 512, and below data line 571, wherein first auxiliary electrode 513 is specifically shown in FIG. 6.

As shown in FIG. 6, first auxiliary electrode 513 is disposed correspondingly below data line 571. Specifically, first auxiliary electrode 513 is disposed below first isolator layer 52, and first auxiliary electrode 513 is disposed between scan line 511 and common electrode 512 along the extension direction of data line 571, and is connected to data line 517 through second via hole 58 of first isolator layer 52 and second isolator layer 55. In the instant embodiment, first auxiliary electrode 513 is preferably formed by first metal layer so as to reduce the material cost.

Therefore, during data signal propagation, in addition to propagation through data line 571, data signal of data line 571 can also be transmitted through second via hole 58 to first auxiliary electrode 513 for propagation in the area disposed with first auxiliary electrode 513. As such, the transmission path of data signal is broadened. Hence, the impedance of data line 571 is reduced to as to improve display quality of liquid crystal display device.

Refer to FIG. 4 again. Similarly, the disposition of auxiliary electrode 501 above scan line 511 can reduce impedance of scan line 511 to improve display quality of liquid crystal display device. Hence, auxiliary electrode 501 further comprises second auxiliary electrode 572, wherein second auxiliary electrode 572 is specifically shown in FIG. 7.

As shown in FIG. 7, second auxiliary electrode 572 is disposed correspondingly above scan line 511. Specifically, second auxiliary electrode 572 is disposed above second isolator layer 55, and second auxiliary electrode 572 is disposed between two adjacent data lines 571 along the extension direction of scan line 511, and is connected to scan line 511 through third via hole 59 of first isolator layer 52 and second isolator layer 55. In the instant embodiment, second auxiliary electrode 572 is preferably formed by second metal layer so as to reduce the material cost.

Therefore, during scan signal propagation, in addition to propagation through scan line 511, scan signal of scan line 511 can also be transmitted through third via hole 59 to second auxiliary electrode 572 for propagation in the area disposed with second auxiliary electrode 572. As such, the transmission path of scan signal is broadened. Hence, the impedance of scan line 511 is reduced to as to improve display quality of liquid crystal display device.

As such, the disposition of second auxiliary electrode 572 above scan line 511 and first auxiliary electrode 513 below data line 571 can reduce impedance of scan line 511and data line 571 so as to improve display quality of liquid crystal display device.

In another preferred embodiment, for cost consideration, it is possible to dispose only second auxiliary electrode 572 above scan line 511 or first auxiliary electrode 513 below data line 571.

When disposing only auxiliary electrode 501 above scan line 511, auxiliary electrode 501 is formed by second metal layer. Auxiliary electrode 501 is disposed correspondingly above scan line 511, and auxiliary electrode 501 is disposed between two adjacent data lines 571 along the extension direction of scan line 511, and is connected to scan line 511 through third via hole 59 of first isolator layer 52 and second isolator layer 55. Specifically, auxiliary electrode 501 has a similar structure to aforementioned second auxiliary electrode 572, and the description will be omitted. Similarly, auxiliary electrode 501 can also reduce impedance of scan line 511 so as to improve display quality of liquid crystal display.

When disposing only auxiliary electrode 501 below data line 571, auxiliary electrode 501 is formed by first metal layer. Auxiliary electrode 501 is disposed correspondingly below data line 571, and auxiliary electrode 501 is disposed between scan line 511 and common electrode 512 along the extension direction of data line 571, and is connected to data line 517 through second via hole 58 of first isolator layer 52 and second isolator layer 55. Specifically, auxiliary electrode 501 has a similar structure to aforementioned first auxiliary electrode 513, and the description will be omitted. Similarly, auxiliary electrode 501 can also reduce impedance of data line 571 so as to improve display quality of liquid crystal display.

The present invention further provides a liquid crystal display device, wherein the liquid crystal display device comprises an array substrate of any embodiment shown in FIGS. 4-7.

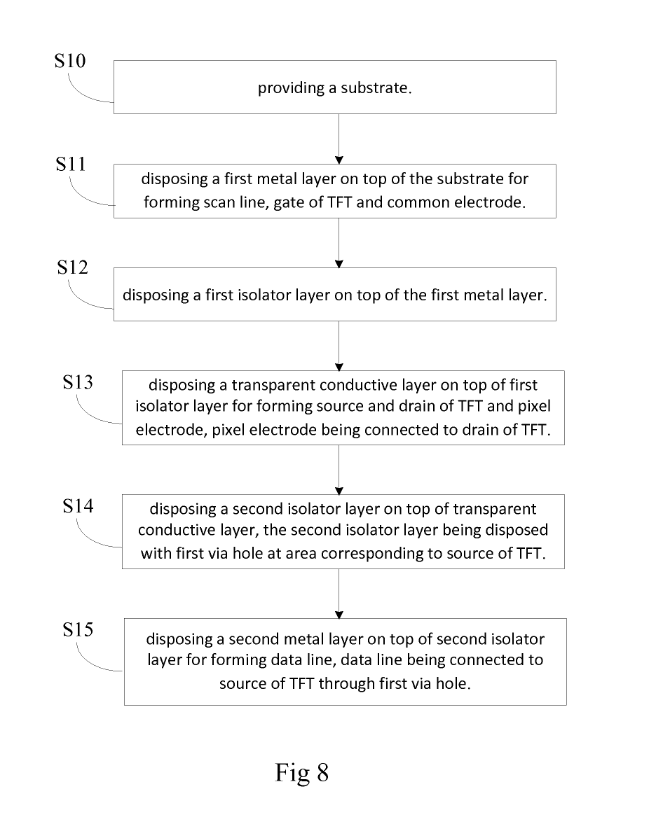

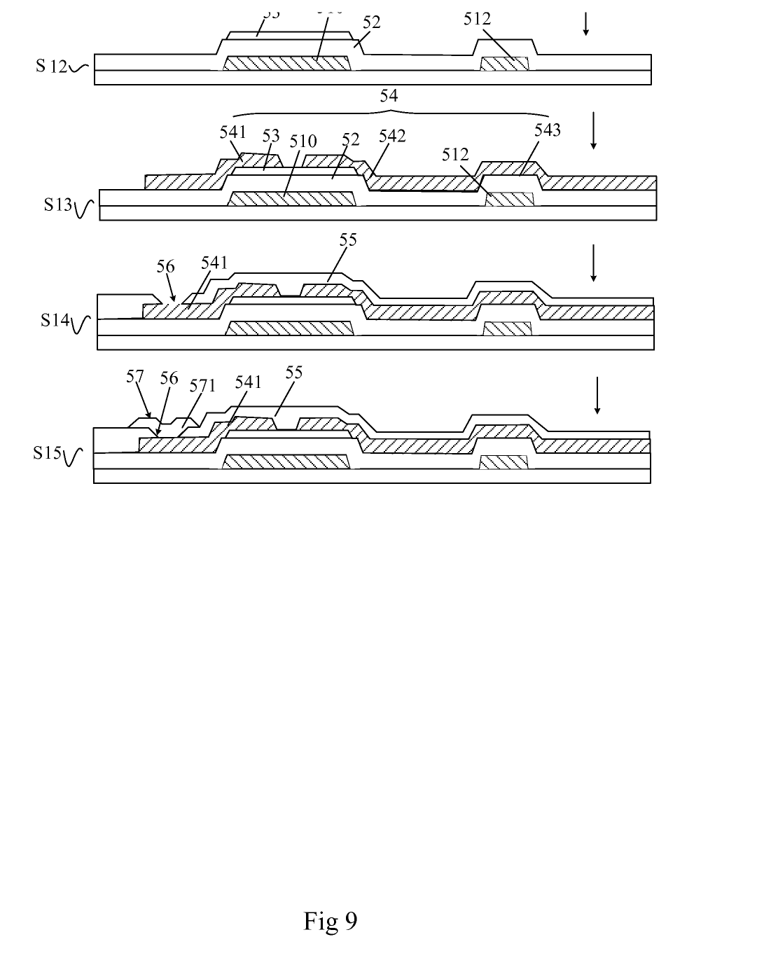

Referring to FIG. 8 and Figure simultaneously, FIG. 8 is a flowchart of the manufacturing method of array substrate according to the present invention; and FIG. 9 is a schematic view showing the 5PEP process of the array substrate in FIG. 8. Refer to FIG. 8 first, the manufacturing method of the array substrate of the present invention comprises the following steps:

Step S10: providing a substrate.

Step S11: disposing a first metal layer on top of the substrate for forming scan line, gate of TFT and common electrode.

Step S12: disposing a first isolator layer on top of the first metal layer.

Step S13: disposing a transparent conductive layer on top of first isolator layer for forming source and drain of TFT and pixel electrode, pixel electrode being connected to drain of TFT.

Step S14: disposing a second isolator layer on top of transparent conductive layer, the second isolator layer being disposed with first via hole at area corresponding to source of TFT.

Step S15: disposing a second metal layer on top of second isolator layer for forming data line, data line being connected to source of TFT through first via hole.

Also refer to FIG. 9. In step S10, a clean, smooth-surfaced glass is provided as substrate 50 of array substrate. Through coating and etching on substrate 50, main components, such as, scan line, data line, pixel electrode and TFT are formed on substrate 50.

Step S11 is to dispose first metal layer 51 on substrate 50, and perform etching on first metal layer 51 to form gate 510 of TFT and scan line 511 (as shown in FIG. 4) and common electrode 512, wherein gate 510 of TFT and scan line 511 are electrically connected so that in subsequent process, scan signal can be supplied through scan line 511to gate 510 of TFT.

After forming gate 510 of TFT and scan line 511 and common electrode 512, step S12 is to from first isolator layer 52 on top of gate 510 of TFT and common electrode 512.

Furthermore, after forming first isolator layer 52, semiconductor layer 53 is formed on top of first isolator layer 52 corresponding to gate 510 of TFT.

Step S13 is to dispose transparent conductive layer 54 on top of first isolator layer 52 and perform etching on transparent conductive layer 54 to form source 541 and drain 542 of TFT and pixel electrode 543, wherein both common electrode 512 and gate 510 of TFT are electrically isolated from transparent conductive layer 54 through first isolator layer 52. Drain 542 of TFT and pixel electrode 543 are connected so that in subsequent process data signal is supplied to pixel electrode 543 through drain 542 to display. Source 541 and drain 542 of TFT are connected respectively to semiconductor layer 53, wherein semiconductor layer 53 acts as a switch to TFT. Specifically:

Gate 510 of TFT acts as control terminal. When scan line 511 supplies scan signal to gate 510 of TFT, semiconductor layer 53 is conductive so that TFT is in a conductive state. Source 541 acting as input terminal of TFT 540 is electrically connected to drain 542 acting as the output terminal through semiconductor layer 53. When no scan signal is inputted to gate 510 of TFT, semiconductor layer 53 is non-conductive so that TFT is in a closed state, and source 541 and drain 542 are electrically isolated.

After disposing transparent conductive layer 54, step S14 is to dispose second isolator layer 55 on top of transparent conductive layer 54. In the instant embodiment, second isolator layer 55 can be passivation layer, or any other isolator layer. No specific restriction is imposed here.

At this point, source 541 of TFT is covered with second isolator layer 55, and source 541 as input terminal of TFT must input required data signal to TFT. Therefore, etching must be performed on second isolator layer 55 to form first via hole 56, wherein first via hole 56 is disposed on second isolator layer 55at location corresponding to source 541 of TFT to enable inputting data signal to source 541.

In the instant embodiment, dry etching means using plasma to perform thin film etching. The present embodiment uses reactive plasma to perform physical bombardment and chemical reaction on second isolator layer 55 so as to form first via hole 56 on second isolator layer 55 to correspond to source 541 of TFT. In other possible embodiments, physical etching or chemical etching can also be used as dry etching to form first via hole 56 on second isolator layer 55. No specific restriction is imposed.

After the above steps, scan line 511, data line 571, common electrode 512 and pixel electrode 543 are all formed on substrate 50, and the formed semiconductor layer 53, gate 510, source 541 and drain 542 form the required TFT of substrate 50. When scan line 511 input scan signal to gate 510 of TFT, semiconductor layer 53 is conductive so that TFT is conductive, and source 541 and drain 542 of TFT are conductive. Data line 571 inputs data signal through via hole 56 to source 541 of TFT, and data signal is outputted from drain 542 to pixel electrode 543.

To improve display quality of liquid crystal display device, the impedance of scan line 511 and/or data line 571 must be reduced. Therefore, the present embodiment further disposes auxiliary electrode. The auxiliary electrode is formed by at least one of first metal layer 51 and second metal layer 57, wherein auxiliary electrode can be disposed in three specific scenarios:

First scenario: only reducing impedance of data line;

Second scenarios: only reducing impedance of scan line; and

Third scenario: reducing impedances of both scan line and data line.

The first scenario is referred to FIG. 6. Auxiliary electrode 501 is formed by first metal layer 51. In Step S11, when forming scan line 511, auxiliary electrode 501 is disposed below data line 571, and auxiliary electrode 501 is disposed between scan line 511 and common electrode 512 and along the extension direction of data line 571. In step S14, after disposing second isolator layer 55, at least two second via holes 58 are disposed above auxiliary electrode 501, second via hole 58 penetrate first isolator layer 52 and second isolator layer 55, and auxiliary electrode 501 is connected to data line 571 through second via hole 58.

Therefore, during data signal propagation, in addition to propagation through data line 571, data signal can also be transmitted through first auxiliary electrode 501 for propagation in the area disposed with first auxiliary electrode 501. As such, the transmission path of data signal is broadened.

Refer to FIG. 7 when auxiliary electrode 501 is disposed for the second scenario. Auxiliary electrode 501 is formed by second metal layer 57. In step S14, after disposing second isolator layer 55, at least two third via holes 59 are disposed above scan line 511, third via hole 59 penetrate first isolator layer 52 and second isolator layer 55. Auxiliary electrode 501 is disposed above scan line 511. Auxiliary electrode 501 is disposed between two adjacent data lines 571 along the extension direction of scan line 511. Auxiliary electrode 501 is connected to scan line 511 through third via hole 59.

Similarly, during scan signal propagation, in addition to propagation through scan line 511, scan signal can also be transmitted through first auxiliary electrode 501 for propagation in the area disposed with first auxiliary electrode 501. As such, the transmission path of scan signal is broadened and the impedance of scan line 511 is reduced.

Refer to FIG. 6 and FIG. 7 when auxiliary electrode 501 is disposed for the third scenario. Auxiliary electrode 501 comprises first auxiliary electrode 513 and second auxiliary electrode 572, wherein first auxiliary electrode 513 is formed by first metal layer 51 and second auxiliary electrode 572 is formed by second metal layer 57.

In the instant embodiment, first auxiliary electrode 513 is disposed below data line 571, and first auxiliary electrode 513 is disposed between scan line 511 and common electrode 512 along the extension direction of data line 571. First auxiliary electrode 513 and data line 571 are connected through second via hole 58 penetrating first isolator layer 52 and second isolator layer 55. The specific disposition step is the same as the aforementioned disposition of auxiliary electrode 501 in the first scenario, and the description is omitted.

In the instant embodiment, second auxiliary electrode 572 is disposed above scan line 511, and second auxiliary electrode 572 is disposed between two adjacent data lines 571 along the extension direction of scan line 511. second auxiliary electrode 572 and scan line 511 are connected through third via hole 59 penetrating first isolator layer 52 and second isolator layer 55. The specific disposition step is the same as the aforementioned disposition of auxiliary electrode 501 in the second scenario, and the description is omitted.

In summary, through disposing auxiliary electrode above scan line and/or below data line, and the auxiliary electrode is formed by at least one of materials of scan line or data line, the present invention can use auxiliary electrode to transmit scan signal or data signal so as to reduce impedance of scan line and/or data line to improve display quality of liquid crystal display device.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An array substrate, the array substrate comprises:
a substrate;
a first metal layer, disposed on top of the substrate for forming scan line, gate of TFT and common electrode;
a first isolator layer, disposed on top of the first metal layer;
a transparent conductive layer, disposed on top of first isolator layer for forming source and drain of TFT and pixel electrode, pixel electrode being connected to drain of TFT;
a second isolator layer, disposed on top of transparent conductive layer, the second isolator layer being disposed with first via hole at area corresponding to source of TFT;
a second metal layer, disposed on top of second isolator layer for forming data line, data line being connected to source of TFT through first via hole;
wherein the array substrate further comprising auxiliary electrode, the auxiliary electrode being formed by at least one of first metal layer and second metal layer, the auxiliary electrode being formed by first metal layer, the auxiliary electrode being connected to data line through second via hole of first isolator layer and second isolator layer for reducing impedance of data line, the auxiliary electrode being disposed correspondingly under the data line, and the auxiliary electrode being disposed along the extension direction of data line between the scan line and common electrode; the auxiliary electrode being formed by second metal layer, the auxiliary electrode being connected to scan line through third via hole of first isolator layer and second isolator layer for reducing impedance of scan line, the auxiliary electrode being disposed correspondingly above the scan line, and the auxiliary electrode being disposed along the extension direction of scan line between two adjacent data lines.

2. The array substrate as claimed in claim 1, characterized in that the auxiliary electrode comprises first auxiliary electrode and second auxiliary electrode, the first auxiliary electrode is formed by first metal layer, and the second auxiliary electrode is formed by second metal layer, wherein:
the first auxiliary electrode is connected to data line through second via hole of first isolator layer and second isolator layer for reducing impedance of data line, the first auxiliary electrode is disposed correspondingly under the data line and the first auxiliary electrode is disposed along the extension direction of data line between the scan line and common electrode; and
the second auxiliary electrode is connected to scan line through third via hole of first isolator layer and second isolator layer for reducing impedance of scan line, the second auxiliary electrode is disposed correspondingly above the scan line and the second auxiliary electrode is disposed along the extension direction of scan line between two adjacent data lines.

3. A liquid crystal display device, which comprises: an array substrate, the array substrate comprising:
a substrate;
a first metal layer, disposed on top of the substrate for forming scan line, gate of TFT and common electrode;
a first isolator layer, disposed on top of the first metal layer;
a transparent conductive layer, disposed on top of first isolator layer for forming source and drain of TFT and pixel electrode, pixel electrode being connected to drain of TFT;
a second isolator layer, disposed on top of transparent conductive layer, the second isolator layer being disposed with first via hole at area corresponding to source of TFT;
a second metal layer, disposed on top of second isolator layer for forming data line, data line being connected to source of TFT through first via hole;
wherein the array substrate further comprising auxiliary electrode, the auxiliary electrode being formed by at least one of first metal layer and second metal layer, for reducing impedance of scan line and/or data line.

4. The liquid crystal display device as claimed in claim 3, characterized in that the auxiliary electrode is formed by first metal layer, the auxiliary electrode is connected to data line through second via hole of first isolator layer and second isolator layer for reducing impedance of data line, the auxiliary electrode is disposed correspondingly under the data line, and the auxiliary electrode is disposed along the extension direction of data line between the scan line and common electrode.

5. The liquid crystal display device as claimed in claim 3, characterized in that the auxiliary electrode is formed by second metal layer, the auxiliary electrode is connected to scan line through third via hole of first isolator layer and second isolator layer for reducing impedance of scan line, the auxiliary electrode is disposed correspondingly above the scan line, and the auxiliary electrode is disposed along the extension direction of scan line between two adjacent data lines.

6. The liquid crystal display device as claimed in claim 3, characterized in that the auxiliary electrode comprises first auxiliary electrode and second auxiliary electrode, the first auxiliary electrode is formed by first metal layer, and the second auxiliary electrode is formed by second metal layer, wherein:
the first auxiliary electrode is connected to data line through second via hole of first isolator layer and second isolator layer for reducing impedance of data line, the first auxiliary electrode is disposed correspondingly under the data line and the first auxiliary electrode is disposed along the extension direction of data line between the scan line and common electrode; and
the second auxiliary electrode is connected to scan line through third via hole of first isolator layer and second isolator layer for reducing impedance of scan line, the second auxiliary electrode is disposed correspondingly above the scan line and the second auxiliary electrode is disposed along the extension direction of scan line between two adjacent data lines.

7. A manufacturing method of array substrate, which comprises:
providing a substrate;
disposing a first metal layer on top of the substrate for forming scan line, gate of TFT and common electrode;
disposing a first isolator layer on top of the first metal layer;
disposing a transparent conductive layer on top of first isolator layer for forming source and drain of TFT and pixel electrode, pixel electrode being connected to drain of TFT;
disposing a second isolator layer on top of transparent conductive layer, the second isolator layer being disposed with first via hole at area corresponding to source of TFT;
disposing a second metal layer on top of second isolator layer for forming data line, data line being connected to source of TFT through first via hole;
wherein further disposing auxiliary electrode, the auxiliary electrode being formed by at least one of first metal layer and second metal layer, for reducing impedance of scan line and/or data line.

8. The manufacturing method as claimed in claim 7, characterized in that the step of disposing first isolator layer on top of first metal layer further comprises:
forming a semiconductor layer on the first isolator layer corresponding to gate of TFT, wherein source and drain of TFT are connected to semiconductor layer respectively.

9. The manufacturing method as claimed in claim 8, characterized in that the auxiliary electrode is formed by first metal layer, the auxiliary electrode is disposed correspondingly under the data line, and the auxiliary electrode is disposed along the extension direction of data line between the scan line and common electrode; the auxiliary electrode is connected to data line through second via hole of first isolator layer and second isolator layer.

10. The manufacturing method as claimed in claim 8, characterized in that the auxiliary electrode is formed by second metal layer, the auxiliary electrode is disposed correspondingly above the scan line, and the auxiliary electrode is disposed along the extension direction of scan line between two adjacent data lines; the auxiliary electrode is connected to scan line through third via hole of first isolator layer and second isolator layer.

11. The manufacturing method as claimed in claim 8, characterized in that the auxiliary electrode comprises first auxiliary electrode and second auxiliary electrode, the first auxiliary electrode is formed by first metal layer, and the second auxiliary electrode is formed by second metal layer, wherein:
the first auxiliary electrode is disposed under the data line and the first auxiliary electrode is disposed along the extension direction of data line between the scan line and common electrode; the first auxiliary electrode is connected to data line through second via hole of first isolator layer and second isolator layer; and
the second auxiliary electrode is disposed correspondingly above the scan line and the second auxiliary electrode is disposed along the extension direction of scan line between two adjacent data lines; the second auxiliary electrode is connected to scan line through third via hole of first isolator layer and second isolator layer.
